(19) United States
(12) Patent Application Publication
(10) Pub. No.: US 2025/0351661 A1
(43) Pub. Date: Nov. 13, 2025

(54) PHOTOELECTRIC DEVICE, AND PREPARATION METHOD THEREOF

(71) Applicant: Shenzhen TCL High-Tech Development Co., Ltd., Shenzhe (CN)

(72) Inventor: Wenjun HOU, Shenzhen (CN)

(73) Assignee: Shenzhen TCL High-Tech Development Co., Ltd., Shenzhen (CN)

(21) Appl. No.: 19/204,607

(22) Filed: May 12, 2025

(30) Foreign Application Priority Data
May 13, 2024 (CN) 202410598950.2

(51) Int. Cl. H10K 50/115; C09K 11/88; H10K 71/15; H10K 85/10; H10K 101/30

(52) U.S. Cl. CPC H10K 50/115; C09K 11/883; H10K 71/15; H10K 85/113; H10K 85/115; H10K 85/146; H10K 85/151; H10K 2101/30

(57) ABSTRACT

Disclosed are a photoelectric device, and a preparation method thereof. The photoelectric device includes a first electrode, a modification layer, an optical functional layer and a second electrode disposed sequentially in stack. A material of the modification layer includes a first organic semiconductor material and a first inorganic nanoparticle. The photoelectric device has a high luminous efficiency.

This application claims priority to Chinese Application No. 202410598950.2, entitled “PHOTOELECTRIC DEVICE, PREPARATION METHOD THEREOF, AND DISPLAY APPARATUS”, filed on May 13, 2024. The entire disclosures of the above application are incorporated herein by reference.

### TECHNICAL FIELD

The present disclosure relates to a field of display technologies, and in particular to a photoelectric device, and a preparation method thereof.

### BACKGROUND

At present, the widely used photoelectric devices are an organic light-emitting diode (OLED) and a quantum dot light-emitting diode (QLED). The OLED has become a mainstream technology in the field of display technologies because of excellent display performances such as self-luminous, simple structure, ultra-thin, fast response speed, wide viewing angle, low power consumption, and flexible display. The QLED has become a strong competitor of the OLED in recent years due to advantages of colour saturation of emitted lights and adjustable wavelength, as well as a high photoluminescence quantum yield and a high electroluminescence quantum yield.

A conventional structure of the OLED or the QLED generally includes an anode, a hole injection layer, a hole transport layer, a light-emitting layer, an electron transport layer, an electron injection layer, and a cathode. Under an action of an electric field, holes generated by the anode and electrons generated by the cathode move, inject into the hole transport layer and the electron transport layer respectively, and finally migrate to the light-emitting layer. When the holes and electrons meet in the light-emitting layer, energy excitons are generated, thereby exciting light-emitting molecules and ultimately generating visible light.

Therefore, a luminous efficiency of a photoelectric device is low and needs to be further improved.

### TECHNICAL SOLUTION

In view of this, the present disclosure provides a photoelectric device, and a preparation method thereof.

According to a first aspect, the present disclosure provides a photoelectric device including a first electrode, a modification layer, an optical functional layer and a second electrode disposed sequentially in stack. A material of the modification layer includes a first organic semiconductor material and a first inorganic nanoparticle.

According to a second aspect, the present disclosure further provides a method for preparing a photoelectric device including:
providing a preform including a first electrode;
disposing a first organic semiconductor material and a first inorganic nanoparticle on the preform to form a modification layer; and
forming an optical functional layer and a second electrode sequentially on the modification layer.

According to a third aspect, the present disclosure further provides another method for preparing a photoelectric device including:
providing a preform including a second electrode and an optical functional layer disposed in stack:
disposing a first organic semiconductor material and a first inorganic nanoparticle on the preform to form a modification layer; and
forming a first electrode on the modification layer.

Accordingly, the present disclosure further provides a display apparatus including the photoelectric device described above or a photoelectric device prepared by the method described above.

The photoelectric device provided by the present disclosure has a high luminous efficiency.

### BRIEF DESCRIPTION OF DRAWINGS

In order to more clearly explain the technical solutions in embodiments of the present disclosure, the following may briefly introduce drawings required in the description of the embodiments. Obviously, the drawings in the following description are only some embodiments of the present disclosure. For those skilled in the art, without paying any creative work, other drawings may be obtained based on these drawings.

FIG. 1 is a schematic diagram of a photoelectric device according to an embodiment of the present disclosure.

FIG. 2 is a schematic diagram of a photoelectric device according to another embodiment of the present disclosure.

FIG. 3 is a flowchart of a method for preparing a photoelectric device according to an embodiment of the present disclosure.

FIG. 4 is a flowchart of a method for preparing a photoelectric device according to another embodiment of the present disclosure.

### DETAILED DESCRIPTION

Technical solutions in embodiments of the present disclosure will be clearly and completely described below in conjunction with drawings in the embodiments of the present disclosure. Obviously, the embodiments are only a part of embodiments of the present disclosure, rather than all the embodiments. Based on the embodiments in the present disclosure, all other embodiments obtained by those skilled in the art without creative work fall within the protection scope of the present disclosure.

In the present disclosure, unless otherwise specified, directional terms such as “upper” or “lower” generally refers to an upper direction or a lower direction in the actual use or working state of a device, specifically a drawing direction in the drawings. “inside” and “outside” are for an outline of the device. In addition, in a description of the present application, a term “including” means “including but not limited to”. Terms as first, second, third and so on are used for indication only, and do not impose numerical requirements or establish order.

In the present disclosure, “and/or” is used to describe an association of associated objects, and means that there may be three relationships, for example, “A and/or B” may refer to three cases: a first case refers to the presence of A alone, a second case refers to the presence of both A and B, and a third case refers to the presence of B alone, where A and B may be singular or plural.

In the present disclosure, “at least one” refers to one or more, and “more” in the “one or more” refers to two or more. “one or more”, “at least one of the followings”, or similar expressions thereof refer to any combination of items listed, including any combination of a singular item or multiple items. For example, “at least one of a, b, or c”, or “at least one of a, b, and c”, may each represent: a, b, c, a-b (i.e., a and b), a-c, b-c, or a-b-c, wherein a, b, and c may be single or plural.

Various embodiments of the present disclosure may be presented in a form of range. It should be understood that a description in the form of range is merely for convenience and brevity, and should not be construed as a hard limitation on the scope of the disclosure. Accordingly, it should be considered that a recited range description has specifically disclosed all possible subranges, as well as a single numerical value within that range. For example, it should be considered that a description of a range from 1 to 6 has specifically disclosed subranges, such as from 1 to 3, from 1 to 4, from 1 to 5, from 2 to 4, from 2 to 6, from 3 to 6, etc., and a single number within the range, such as 1, 2, 3, 4, 5, 6, and the like, which is applicable for any range. Additionally, whenever a range of values is indicated herein, it is meant to include any recited number (fractional or integer) within the indicated range.

In a photoelectric device, a material of an electron functional layer is usually an inorganic material, and a material of a hole functional layer is usually an organic material, resulting in an electron migration rate is much higher than a hole migration rate. Electrons easily pass through an optical functional layer, accumulate and form a built-in electric field at an interface between the hole functional layer and the optical functional layer, and some electrons may transition to the hole functional layer, resulting in a deterioration of the material of the hole transport layer and a degradation of a performance of the photoelectric device. Technical solutions of the present disclosure are as follows:

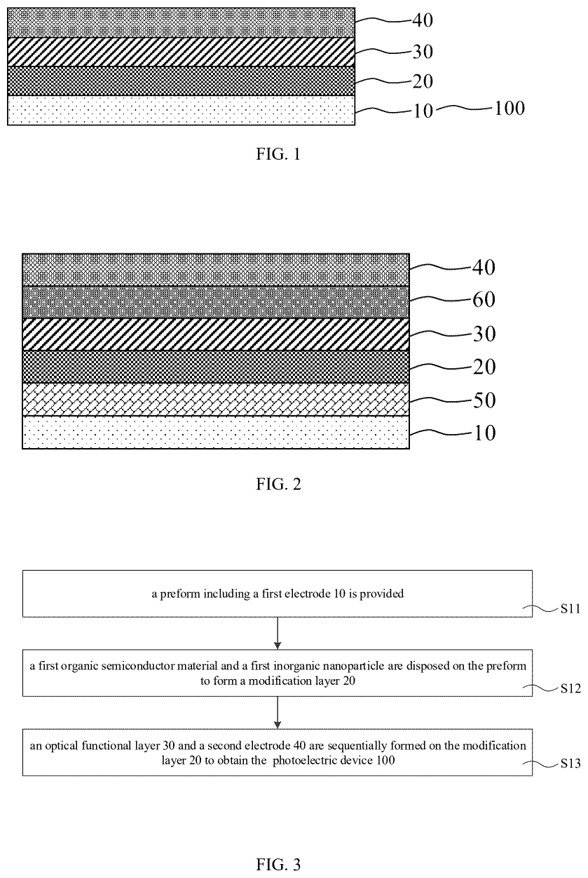

In a first aspect, referring to FIG. 1, an embodiment of the present disclosure provides a photoelectric device 100, including a first electrode 10, a modification layer 20, an optical functional layer 30, and a second electrode 40 disposed sequentially in stack. A material of the modification layer 20 includes a first organic semiconductor material and a first inorganic nanoparticle.

In the photoelectric device 100 provided by the present disclosure, the modification layer 20 is added between the first electrode 10 and the optical functional layer 30. The first organic semiconductor material in the modification layer 20 may ensure a transmission of carriers between the first electrode 10 and the optical functional layer 30. Opposite carriers transmitted from the second electrode 40 to an interface between the modification layer 20 and the optical functional layer 30 may recombine with the carriers to form excitons. The excitons may be transmitted to the first inorganic nanoparticle through energy resonance transfer, thereby promoting luminescence. Moreover, by recombining the carriers with the opposite carriers, it is possible to avoid damage and destruction of the first organic semiconductor material by the carriers, and make the first organic semiconductor material fully exhibit an excellent performance of promoting carrier transport, thereby improving a luminous efficiency of the photoelectric device 100.

The carriers refer to holes or electrons, and the opposite carriers refer to carriers with an opposite type to the carriers. Specifically, when the carriers are holes, the opposite carriers are electrons, and when the carriers are electrons, the opposite carriers are holes.

In some embodiments, an average particle size of the first inorganic nanoparticle ranges from 2 nm to 10 nm, such as 3 nm, 4 nm, 5 nm, 6 nm, 7 nm, 8 nm, or 9 nm. A particle size of each inorganic nanoparticle in the present disclosure is measured by a transmission electron microscope.

In some embodiments, the first inorganic nanoparticle includes a first quantum dot.

Furthermore, the first quantum dot may be selected from but not limited to one or more of a quantum dot with a single component, a quantum dot with a core-shell structure, and a perovskite-type quantum dot.

A material of the quantum dot with a single component, a core material of the quantum dot with a core-shell structure, and a shell material of the quantum dot with a core-shell structure may be each independently selected from but not limited to one or more of a group II-VI compound, a group IV-VI compound, a group III-V compound, and a group I-III-VI compound. A shell layer of the quantum dot with a core-shell structure is one or more layers. The group II-VI compound may be selected from but not limited to one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, and HgZnSTe. The group IV-VI compound may be selected from but not limited to one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, and SnPbSTe. The group III-V compound may be selected from but not limited to one or more of GaN, GaP. GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb. The group I-III-VI compound may be selected from but not limited to one or more of CuInS₂, CuInSc₂, and AgInS₂.

As an example, the quantum dot with a core-shell structure may be selected from but not limited to one or more of CdSe/CdSeS/CdS, InP/ZnSeS/ZnS, CdZnSe/ZnSe/ZnS. CdSeS/ZnSeS/ZnS, CdSc/ZnS, CdSe/ZnSe/ZnS, ZnSe/ZnS, ZnSeTe/ZnS. CdSe/CdZnSeS/ZnS, and InP/ZnSe/ZnS. “/” in the above description such as CdSe/ZnS means that a substance after “/” (as the shell layer) wraps a substance before “/” (as the core).

The perovskite-type quantum dot has a general structural formula of AMX₃, where A is selected from Cs⁺, CH₃(CH₂)ₙ₋₂NH₃⁺, or [NH₃(CH₂)ₙNH₃]²⁺, n is greater or equal to 2, M is a divalent metal cation which is selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, and Eu²⁺, and X is selected from one or more of Cl⁻, Br⁻, and I⁻.

In some embodiments, the first organic semiconductor material includes a first P-type organic semiconductor material.

Furthermore, the first P-type organic semiconductor material includes one or more of 4,4′-Bis(N-carbazolyl)-1,1′-biphenyl, N,N′-diphenyl-N,N′-bis(1-naphthyl)-1,1′-biphenyl-4,4′-diamine, N,N′-bis(3-methylphenyl)-N,N′-diphenyl-benzidine, N,N′-bis(3-methylphenyl)-N,N′-bis(phenyl)-spiro, N,N′-bis(4-(N,N′-diphenyl-amino) phenyl)-N,N′-diphenylbenzidine, 4,4′,4′-tris(N-carbazolyl)-triphenylamine, 4′,4″-tris(carbazol-9-yl)-triphenylamine, trichloroisocyanuric acid, a terbium-doped phosphate-based green luminescent material, hexaazatriphenylenchexacabonitrile, 4,4′,4″-tris(N-3-methylphenyl-N-phenylamino)triphen, poly(9,9-dioctylfluorene-co-N-(4-butylphenyl) diphenylamine), poly[(9,9′-dioctylfluorene-2,7-diyl)-co-(4,4′-(N-(4-sec-butylphenyl)diphenylamine)], poly[N,N′-bis(4-butylphenyl)-N,N′-bis(phenyl)-benzi, polyaniline, polypyrrole, poly(phenylenevinylene), poly[2-methoxy-5-(3′,7′-dimethyloctyloxy)-1,4-phenylenevinylene], copper(II) phthalocyanine, aromatic tertiary amine, polynuclear aromatic tertiary amine, N,N,N′,N′-tetraphenylbenzidine, PEDOT, PEDOT:PSS and derivatives thereof, PEDOT:PSS doped with s-MoO₃, poly(N-vinylcarbazole) and derivatives thereof, polymethacrylate and derivatives thereof, poly(9,9-octylfluorene) and derivatives thereof, poly(spirofluorene) and derivatives thereof, N,N′-bis(naphthalen-1-yl)-N,N′-diphenylbenzidine, spiro-NPB, nano-polycrystalline diamond, microcrystalline cellulose, and tetracyanoquinone dimethane.

In some embodiments, in the modification layer 20, a mass ratio of the first organic semiconductor material to the first inorganic nanoparticle is (90˜99):(1˜10), such as 91:9, 92:8, 93:7. 94:6, 95:5, 96:4, 97:3, or 98:2. Within a range of the mass ratio, carrier transport from the first electrode 10 to the optical functional layer 30 is facilitated, and the excitons formed by recombination of opposite carriers and carriers at the interface of the modification layer 20 and the optical functional layer 30 emit light through the first inorganic nanoparticle.

In some embodiments, a HOMO energy level of the modification layer 20 ranges from −6.0 eV to −4.8 eV, such as −5.0 eV, −5.2 eV, −5.4 eV, −5.5 eV, or −5.8 eV. A highest occupied molecular orbital and a lowest unoccupied molecular orbital in a molecular orbital are crucial in a reaction, and electrons on the highest occupied molecular orbital (HOMO) are most relaxed and are most easily excited into the lowest unoccupied molecular orbital (LUMO). Each HOMO energy level in the present disclosure is measured by cyclic voltammetry, where the cyclic voltammetry is a commonly used electrochemical research method. The cyclic voltammetry controls electrode potentials to be repeatedly scanned once or more times in a triangular waveform at different rates over time. A potential range is such that different reduction and oxidation reactions may alternately occur on the electrode, and a current-potential curve is recorded. According to a shape of the curve, a reversibility degree of electrode reactions, a possibility of intermediate, phase boundary adsorption or new phase formation, and properties of coupling chemical reaction may be judged. A reading of an oxidation onset potential is obtained according to a cyclic voltammetry test. E plus Esce is a first ionization energy (Ip), and a HOMO energy level is equal to −Ip.

In some embodiments, an average thickness of the modification layer 20 ranges from 5 nm to 15 nm, such as 6 nm, 8 nm, 10 nm, 12 nm, or 14 nm.

In some embodiments, the optical functional layer 30 includes an emission material layer, and a material of the emission material layer includes an organic emission material or a second inorganic nanoparticle.

The organic emission material includes one or more of 4,4′-bis(N-carbazole)-1,1′-biphenyl: tris[2-(p-tolyl)pyridinyl iridium (III)], 4.4′,4″-tris(carbazol-9-yl)triphenylamine: tris[2-(p-tolyl)pyridinyl iridium], diarylanthracene derivatives, stilbene aromatic derivatives, pyrene derivatives, fluorene derivatives, a TBPe fluorescent material, a TTPX fluorescent material, a TBRb fluorescent material, a DBP fluorescent material, a delayed fluorescence material, a TTA material, a TADF material, a polymer including a B-N covalent, a HLCT material, and an Exciplex luminescent material.

In some embodiments, an average particle size of the second inorganic nanoparticle ranges from 7 nm to 15 nm, such as 8n m, 9 nm, 10 nm, 11 nm, 12 nm, 13 nm, or 14 nm.

A material of the second inorganic nanoparticle and a material of the first inorganic nanoparticle are the same or different.

In some embodiments, the second inorganic nanoparticle includes a second quantum dot. The second quantum dot may be selected from but not limited to one or more of a quantum dot with a single component, a quantum dot with a core-shell structure, and a perovskite-type quantum dot.

Furthermore, a material of the quantum dot with a single component, a core material of the quantum dot with a core-shell structure, and a shell material of the quantum dot with a core-shell structure may be each independently selected from but not limited to one or more of a group II-VI compound, a group IV-VI compound, a group III-V compound, and a group I-III-VI compound. A shell layer of the quantum dot with a core-shell structure is one or more layers. The group II-VI compound may be selected from but not limited to one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, and HgZnSTe. The group IV-VI compound may be selected from but not limited to one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, and SnPbSTe. The group III-V compound may be selected from but not limited to one or more of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb. The group I-III-VI compound may be selected from but not limited to one or more of CuInS₂, CuInSe₂, and AgInS₂.

As an example, the quantum dot with a core-shell structure may be selected from but not limited to one or more of CdSe/CdSeS/CdS, InP/ZnSeS/ZnS, CdZnSe/ZnSe/ZnS, CdSeS/ZnSeS/ZnS. CdSe/ZnS. CdSe/ZnSe/ZnS. ZnSe/ZnS, ZnSeTe/ZnS. CdSe/CdZnSeS/ZnS, and InP/ZnSe/ZnS. “/” in the above description such as CdSe/ZnS means that a substance after “/” (as the shell layer) wraps a substance before “/” (as the core).

The perovskite-type quantum dot has a general structural formula of AMX₃, where A is selected from Cs⁺, CH₃(CH₂)ₙ₋₂NH₃⁺, or [NH₃(CH₂)ₙNH₃]²⁺, n is greater or equal to 2, M is a divalent metal cation which is selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, and Eu²⁺, and X is selected from one or more of Cl⁻, Br⁻, and I⁻.

In some embodiments, a thickness of the optical functional layer 30 ranges from 10nm to 50 nm, such as 20 nm, 30 nm, or 40 nm.

In some embodiments, each of the first electrode 10 and the second electrode 40 independently includes one or more of a metal, a carbon material, and a metal oxide. The metal includes one or more of Al, Ag, Cu, Mo, Au, Ba, Ca, Yb and Mg. The carbon material includes one or more of graphite, carbon nanotube, graphene, and carbon fiber. The metal oxide includes one or more of indium tin oxide (ITO), fluorine-doped tin oxide (FTO), antimony tin oxide (ATO), aluminium-doped zinc oxide (AZO), gallium-doped zinc oxide (GZO), indium-doped zinc oxide (IZO), magnesium-doped zinc oxide (MZO), and MoO₃.

Each of the first electrode 10 and the second electrode 40 may be a composite electrode, and the composite electrode includes one or more of AZO/Ag/AZO, AZO/Al/AZO, ITO/Ag/ITO, ITO/Al/ITO, ZnO/Ag/ZnO, ZnO/Al/ZnO, ZnS/Ag/ZnS, ZnS/Al/ZnS, TiO₂/Ag/TiO₂, and TiO₂/Al/TiO₂. “/” represents a laminated structure, and for example, AZO/Ag/AZO represents a composite electrode including an AZO layer, an Ag layer, and an AZO layer disposed sequentially in stack.

In some embodiments, referring to FIG. 2. the photoelectric device 100 further includes one or more of a first carrier functional layer 50 and a second carrier functional layer 60, where the first carrier functional layer 50 disposed between the first electrode 10 and the modification layer 20, and a second carrier functional layer 60 disposed between the optical functional layer 30 and the second electrode 40.

In some embodiments, the first carrier functional layer 50 is a hole functional layer, and the second carrier functional 60 is an electron functional layer. Accordingly, the first electrode 10 is an anode, and the second electrode 40 is a cathode. Leakage electrons passing through the optical functional layer 30 may recombine with holes in the modification layer 20 to form excitons, and the excitons may be transferred to the first inorganic nanoparticle by energy resonance to emit light. The leakage electrons may also avoid damage to a hole functional layer material.

The hole functional layer includes one or more of a hole injection layer and a hole transport layer.

The electron functional layer includes one or more of an electron injection layer and an electron transport layer.

In some embodiments, a material of the hole functional layer includes a second organic semiconductor material.

In some embodiments, the second organic semiconductor material includes a second P-type organic semiconductor material.

Furthermore, the second P-type organic semiconductor material includes one or more of 4,4′-Bis(N-carbazolyl)-1,1′-biphenyl, N,N′-diphenyl-N,N′-bis(1-naphthyl)-1,1′-biphenyl-4,4′-diamine, N,N′-bis(3-methylphenyl)-N,N′-diphenyl-benzidine, N,N′-bis(3-methylphenyl)-N,N′-bis(phenyl)-spiro, N,N′-bis(4-(N,N′-diphenyl-amino)phenyl)-N,N′-diphenylbenzidine, 4,4′,4′-tris(N-carbazolyl)-triphenylamine, 4′,4″-tris(carbazol-9-yl)-triphenylamine, trichloroisocyanuric acid, a terbium-doped phosphate-based green luminescent material, hexaazatriphenylenchexacabonitrile, 4,4′,4″-tris(N-3-methylphenyl-N-phenylamino)triphen, poly(9,9-dioctylfluorene-co-N-(4-butylphenyl)diphenylamine), poly[(9,9′-dioctylfluorene-2,7-diyl)-co-(4,4′-(N-(4-sec-butylphenyl) diphenylamine)], poly[N,N′-bis(4-butylphenyl)-N,N′-bis(phenyl)-benzi, polyaniline, polypyrrole, poly(phenylenevinylene), poly[2-methoxy-5-(3′,7′-dimethyloctyloxy)-1,4-phenylenevinylene], copper(II) phthalocyanine, aromatic tertiary amine, polynuclear aromatic tertiary amine, N,N,N′,N′-tetraphenylbenzidine, PEDOT, PEDOT:PSS and derivatives thereof, PEDOT: PSS doped with s-MoO₃, poly(N-vinylcarbazole) and derivatives thereof, polymethacrylate and derivatives thereof, poly(9,9-octylfluorene) and derivatives thereof, poly(spirofluorene) and derivatives thereof, N,N′-bis(naphthalen-1-yl)-N,N′-diphenylbenzidine, spiro-NPB, nano-polycrystalline diamond, microcrystalline cellulose, and tetracyanoquinone dimethane.

The first organic semiconductor material and the second organic semiconductor material are the same or different.

In some embodiments, an absolute value of a HOMO energy level of the hole functional layer is less than an absolute value of a HOMO energy level of the modification layer 20, thereby facilitating hole injection and hole transport.

Furthermore, the HOMO energy level of the hole functional layer ranges from −5.5 eV˜−4.8 eV, such as −4.9 eV, −5.0 eV, −5.4 eV, −5.2 eV, −5.3 eV, or −5.4 eV.

In some embodiments, a thickness of the hole functional layer ranges from 5 nm˜35 nm, such as 10 nm, 15 nm, 20 nm, 25 nm, or 30 nm.

In some embodiments, a material of the electron functional layer includes a first doped-type metal oxide particle, a first undoped-type metal oxide particle, a group IIB-VIA semiconductor material, a group IIIA-VA semiconductor material, and a group IB-IIIA-VIA semiconductor material. The first undoped-type metal oxide particle includes one or more of ZnO, TiO₂, SnO₂, ZrO₂, and Ta₂O₅. A metal oxide in the first doped metal oxide particle includes one or more of ZnO, TiO₂, SnO₂, ZrO₂, Ta₂O₅ and Al₂O₃, and a doping element of the first doped-type metal oxide particle includes one or more of Al, Mg, Li, Mn, Y, La, Cu, Ni, Zr, Ce, In, and Ga. The group IIB-VIA semiconductor material includes one or more of ZnS, ZnSe, and CdS. The group IIIA-VA semiconductor material includes one or more of InP and GaP. The group IB-IIIA-VIA semiconductor material includes one or more of CuInS and CuGaS.

In a second aspect, referring to FIG. 3, an embodiment of the present disclosure provides a method for preparing a photoelectric device including steps S11˜S13.

In step S11, a preform including a first electrode 10 is provided.

In step S12, a first organic semiconductor material and a first inorganic nanoparticle are disposed on the preform to form a modification layer 20.

In step S13, an optical functional layer 30 and a second electrode 40 are sequentially formed on the modification layer 20 to obtain the photoelectric device 100.

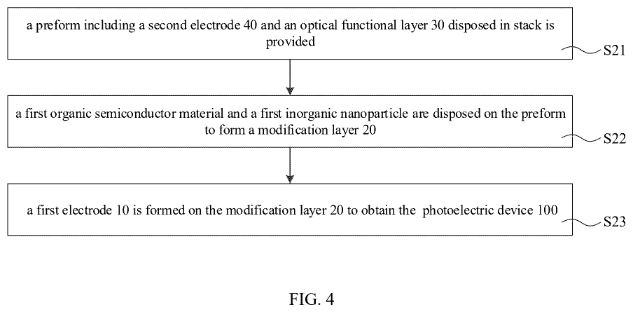

Referring to FIG. 4, an embodiment of the present disclosure provides another method for preparing a photoelectric device including steps S21˜S23.

In step S21, a preform including a second electrode 40 and an optical functional layer 30 disposed in stack is provided.

In step S22, a first organic semiconductor material and a first inorganic nanoparticle are disposed on the preform to form a modification layer 20.

In step S23, a first electrode 10 is formed on the modification layer 20 to obtain the photoelectric device 100.

In some embodiments, in step S11 and step S23, the preform further includes a first carrier functional layer 50 stacked with the first electrode 10. In other words, step S12 includes that the first organic semiconductor material and the first inorganic nanoparticle are disposed on the first carrier functional layer 50.

Accordingly, in some embodiments, step S23 includes that the first carrier functional layer 50 is formed on the modification layer 20, then the first electrode 10 is formed on the first carrier functional layer 50.

In some embodiments, in step S12 and step S23, a mixed liquid including the first organic semiconductor material, the first inorganic nanoparticle, and a solvent is provided, and then the mixed liquid is disposed on the preform to form the modification layer 20.

In some embodiments, in the mixed liquid, a mass ratio of the first organic semiconductor material to the first inorganic nanoparticle is (90˜99):(1˜10), such as 91:9, 92:8, 93:7, 94:6, 95:5, 96:4, 97:3, or 98:2. Within a range of the mass ratio, carrier transport from the first electrode 10 to the optical functional layer 30 is facilitated, and the excitons formed by recombination of opposite carriers and carriers at the interface of the modification layer 20 and the optical functional layer 30 emit light through the first inorganic nanoparticle.

In some embodiments, in the mixed liquid, a mass concentration of the first organic semiconductor material ranges from 8 mg/mL to 15 mg/mL, such as 9 mg/mL, 10 mg/mL, 11 mg/mL, 12 mg/mL, 13 mg/mL, or 14 mg/mL. Within a range of the mass concentration above, it is conducive to dissolution and dispersion of the first organic semiconductor material.

In some embodiments, the solvent includes one or more of chlorobenzene, diethylene glycol monobutyl ether, 3-methoxy-1-butanol, triethylene glycol monobutyl ether, diglyme, methanol, ethanol, 1-propanol, butanol, ethylene glycol, isopropanol, glycerol, dimethyl sulfoxide, acetone, acetophenone, tetrahydrofuran, N,N-dimethylformamide,, ethyl acetate, pyrrole, butyric acid, and cresol.

In some embodiments, after disposing the mixed liquid on the preform, a thermal annealing is performed.

Furthermore, a temperature of the thermal annealing ranges from 80° C. to 120° C., such as 90° C., 100° C., or 110° C. The time of the thermal annealing ranges from 5 minutes to 15 minutes, such as 6 minutes, 8 minutes, 10 minutes, 12 minutes, or 14 minutes. Thus, under conditions of the thermal annealing above, it is conducive to removing a solvent from the mixed solution sufficiently.

In some embodiments, in step S13, forming the optical functional layer 30 on the modification layer 20 includes that a second carrier functional layer 60 is formed on the modification layer 20, then the second electrode 40 is formed on the second carrier functional layer 60.

Accordingly, in some embodiments, the preform further includes the second carrier functional layer 60 disposed between the first electrode 10 and the optical functional layer 30.

In a third aspect, an embodiment of the present disclosure provides a display apparatus including the photoelectric device as described above.

The display apparatus may be any electronic product with a display function, including but not limited to a smartphone, a tablet computer, a notebook computer, a digital camera, a digital video camera, a smart wearable device, a smart weighing electronic scale, a vehicle display, a television or an electronic book. The smart wearable device may be, for example, a smart bracelet, a smart watch, a virtual reality (VR) helmet, or the like.

In the following, the present disclosure is specifically described by specific embodiments, and the following examples are only partial examples of the present disclosure and are not limited to the present disclosure.

### Example 1

The present embodiment provided a photoelectric device and a preparation method thereof.

A method for preparing the photoelectric device included steps S1˜S7.

In step S1, a substrate with a patterned electrode made of ITO was cleaned, then a surface of the substrate was treated with UV-ozone for 5 minutes to form an anode.

In step S2, a polyaniline solution was spin-coated on the anode at a rotating speed of 5000 r/min for 30 seconds to form a film, and spin coating was followed by a thermal annealing treatment at 200° C. for 30 minutes to form a hole injection layer with a thickness of 30 nm.

In step S3, a TFB solution was spin-coated on the hole injection layer at a rotating speed of 3000 r/min for 30 seconds to form a film, CAS number of the TFB is 220797-16-0, and spin coating was followed by a thermal annealing treatment at 150° C. for 10 minutes to form a hole transport layer with a thickness of 25 nm.

In step S3, a mixed solution consisting of PVK and InP was spin-coated on the hole transport layer at a rotating speed of 2000 r/min for 30 seconds to form a film, and spin coating was followed by a thermal annealing treatment at 100° C. for 10 minutes to form a modification layer with a thickness of 10 nm. In the mixed solution, a mass ratio of PVK to InP was 96:4, and an average particle size of InP was 8 nm.

In step S4, a quantum dot of CdZnSe/ZnSe/ZnS was spin-coated on the modification layer, and spin coating was followed by a thermal annealing treatment at 100° C. for 5 minutes to form an optical functional layer with a thickness of 20 nm. An emission wavelength of the quantum dot was 625 nm, and an average particle size of the quantum dot was 10 nm.

In step S5, an ethanol dispersion of Zn_{0.9}Mg_{0.1}O was spin-coated on the optical functional layer at a rotating speed of 3000 r/min for 30 seconds to form a film, and spin coating was followed by a thermal annealing treatment at 100° C. for 15 minutes to form an electron transport layer with a thickness of 30 nm.

In step S6, silver was evaporated by a thermal evaporation under a vacuum degree not higher than 3×10⁴Pa to form a cathode with a thickness of 80 nm.

In step S7, after the cathode was formed, the substrate was encapsulated by an epoxy resin obtain the photoelectric device.

### Example 2

The present embodiment was essentially the same as the Example 1, except that a mass ratio of PVK to InP was 99:1.

### Example 3

The present embodiment was essentially the same as the Example 1, except that a mass ratio of PVK to InP was 90:10.

### Example 4

The present embodiment was essentially the same as the Example 1, except that a mass ratio of PVK to InP was 99.5:0.5.

### Example 5

The present embodiment was essentially the same as the Example 1, except that a mass ratio of PVK to InP was 85:15.

### Example 6

The present embodiment was essentially the same as the Example 1, except that PVK was replaced with polythiophene.

### Example 7

The present embodiment was essentially the same as the Example 1, except that PVK was replaced with TFB.

### Example 8

The present embodiment was essentially the same as the Example 1, except that InP was replaced with CdS.

### Example 9

The present embodiment was essentially the same as the Example 1, except that InP was replaced with CdZnSe/ZnSe/ZnS.

### Example 10

The present embodiment was essentially the same as the Example 1, except that the thickness of the modification layer was 15 nm.

### Example 11

The present embodiment was essentially the same as the Example 1, except that the thickness of the modification layer was 5 nm.

### Comparative Example 1

The present comparative embodiment was essentially the same as the Example 1, except that the modification layer was omitted.

### Comparative Example 2

The present comparative embodiment was essentially the same as the Example 1, except that the modification layer was omitted, and the material of the optical functional layer was PVK and a quantum dot of CdZnSe/ZnSe/ZnS. A mass ratio of PVK to the quantum dot was 95:5.

A current efficiency (C.E) and a lifetime (T95@ lk nit) of each photoelectric device in Examples 1˜11 and Comparative Examples 1˜2 are tested respectively, and the results are shown in Table 1.

The current efficiency (C.E) is tested and calculated by a Keithley 2400 high-precision digital source meter, an Ocean Optic USB2000+spectrometer and a LS-160 luminance meter.

A method for testing lifetime (T95@1k nit) includes that driven by a constant current or a constant voltage, a time required for each photoelectric device to decay from the maximum brightness to 95% thereof is defined as T95. T95 is a measured life. In order to shorten a test cycle, a device lifetime testing is usually carried out by accelerating device aging at high brightness, and a lifetime at high brightness is obtained by an attenuation fitting formula. For example, the lifetime at 1k nit is defined as T95@lk nit. A specific calculation formula is as follows:

$$T {95}_{L} = T {95}_{H} { ( \frac{{L}_{H}}{{L}_{L}} )}^{A} ;$$

In the formula, T95_{L} is a lifetime at low brightness, T95_{H} is a measured lifetime at high brightness, L_{H} is the highest brightness of the device, L_{L} is 1k nit, and A is an acceleration factor which is 1.7.

TABLE 1

| | C.E | T95@1k nit |
|---|---|---|
| | (cd/A) | (h) |
| Example 1 | 25 | 3500 |
| Example 2 | 24 | 3400 |
| Example 3 | 24 | 3300 |
| Example 4 | 22 | 2800 |
| Example 5 | 22 | 2900 |
| Example 6 | 21 | 2900 |
| Example7 | 22 | 4000 |
| Example 8 | 24 | 3700 |
| Example 9 | 23 | 4200 |
| Example 10 | 22 | 3200 |
| Example 11 | 22 | 3300 |
| Comparative Example 1 | 20 | 2700 |
| Comparative Example 2 | 20 | 2750 |

According to Examples 1˜5 and Comparative Examples 1˜2, adding the modification layer including an organic semiconductor material and a quantum dot between the hole transport layer and the optical functional layer may improve the current efficiency and lifetime of the photoelectric device.

In Examples 1 to 3, a ratio of the organic semiconductor material to the quantum dot is within a preferred range provided in the present disclosure, thus the current efficiency of each photoelectric device in Examples 1 to 3 is higher than that of each photoelectric device in Example 4 and Example 5, and the lifetime of each photoelectric device in Examples 1 to 3 is longer than that of each photoelectric device in Example 4 and Example 5. Comparative Example 2 adds an organic semiconductor material to the optical functional layer, and the lifetime of the photoelectric device in Comparative Example 2 is slightly improved compared to Comparative Example 1, but the performance of the photoelectric device in Comparative Example 2 is still far inferior to that of Example 1.

As can be seen from Examples 1, 6 to 9 and Comparative Example 1, whether the organic semiconductor material or the quantum dot is replaced, Examples 1, 6 to 9 may effectively improve performances of the photoelectric devices compared with Comparative Example 1. In Example 7, the organic semiconductor material is consistent with the material of the hole transport layer, and the current efficiency and lifetime of the photoelectric device are significantly higher than those of Example 6. In Example 9, the quantum dot is consistent with the material of the optical functional layer, and the current efficiency is not significantly different from that of Example 8, but the lifetime is significantly higher than that of Example 8.

As can be seen from Examples 1, 10 to 11 and Comparative Example 1, the thickness of the modification layer has a certain influence on the performance of the photoelectric device. Within a thickness range of the modification layer provided in the present disclosure, When the thickness of the modification layer is appropriate, the performance of the photoelectric device is better, and the current efficiency and lifetime are both improved.

The photoelectric device, and the preparation method thereof by embodiments of the present disclosure are described in detail above, and specific examples have been applied herein to illustrate principles and implement measures. The foregoing description of embodiments is provided merely to help understand a method and a core idea of the present disclosure. Those skilled in the art may change specific embodiments and scope of the present disclosure according to ideas of the present disclosure. In summary, contents of the specification should not be construed as limiting the present disclosure.

What is claimed is:

1. A photoelectric device comprising a first electrode, a modification layer, an optical functional layer and a second electrode disposed sequentially in stack:
wherein a material of the modification layer comprises a first organic semiconductor material and a first inorganic nanoparticle.

2. The photoelectric device according to claim 1, wherein in the modification layer, a mass ratio of the first organic semiconductor material to the first inorganic nanoparticle is (90˜99):(1˜10).

3. The photoelectric device according to claim 1, wherein a HOMO energy level of the modification layer ranges from −6.0 eV to −4.8 eV;
an average particle size of the first inorganic nanoparticle ranges from 2 nm to 10 nm.

4. The photoelectric device according to claim 1, wherein a first organic semiconductor material comprises a first P-type organic semiconductor material, and a first inorganic nanoparticle comprises a first quantum dot, where the first P-type organic semiconductor material comprises one or more of 4,4′-Bis(N-carbazolyl)-1,1′-biphenyl, N,N′-diphenyl-N,N′-bis(1-naphthyl)-1,1′-biphenyl-4,4′-diamine, N,N′-bis(3-methylphenyl)-N,N′-diphenyl-benzidine, N,N′-bis(3-methylphenyl)-N,N′-bis(phenyl)-spiro, N,N′-bis(4-(N,N′-diphenyl-amino)phenyl)-N,N′-diphenylbenzidine, 4,4′,4′-tris(N-carbazolyl)-triphenylamine, 4′,4″-tris(carbazol-9-yl)-triphenylamine, trichloroisocyanuric acid, a terbium-doped phosphate-based green luminescent material, hexaazatriphenylenehexacabonitrile, 4,4′,4″-tris(N-3-methylphenyl-N-phenylamino)triphen, poly(9,9-dioctylfluorene-co-N-(4-butylphenyl)diphenylamine), poly[(9,9′-dioctylfluorene-2,7-diyl)-co-(4,4′-(N-(4-sec-butylphenyl)diphenylamine)], poly[N,N′-bis(4-butylphenyl)-N,N′-bis(phenyl)-benzi, polyaniline, polypyrrole, poly(phenylenevinylene), poly[2-methoxy-5-(3′,7′-dimethyloctyloxy)-1,4-phenylenevinylene], copper(II) phthalocyanine, aromatic tertiary amine, polynuclear aromatic tertiary amine, N,N,N′,N′-tetraphenylbenzidine, PEDOT, PEDOT:PSS and derivatives thereof, PEDOT: PSS doped with s-MoO₃, poly(N-vinylcarbazole) and derivatives thereof, polymethacrylate and derivatives thereof, poly(9,9-octylfluorene) and derivatives thereof, poly(spirofluorene) and derivatives thereof, N,N′-bis(naphthalen-1-yl)-N,N′-diphenylbenzidine, spiro-NPB, nano-polycrystalline diamond, microcrystalline cellulose, and tetracyanoquinone dimethane.

5. The photoelectric device according to claim 1, wherein the optical functional layer comprises an emission material layer, and a material of the emission material layer comprises an organic emission material or a second inorganic nanoparticle.

6. The photoelectric device according to claim 5, wherein the second inorganic nanoparticle comprises a second quantum dot;
the first quantum dot and the second quantum dot are each independently selected from one or more of a quantum dot with a single component, a quantum dot with a core-shell structure, and a perovskite-type quantum dot; a material of the quantum dot with the single component, a core material of the quantum dot with the core-shell structure, and a shell material of the quantum dot with the core-shell structure are each independently selected from one or more of a group II-VI compound, a group IV-VI compound, a group III-V compound, a group I-III-VI compound; a shell layer of the quantum dot with a core-shell structure is one or more layers;
the group II-VI compound is selected from one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, and HgZnSTe; the group IV-VI compound is selected from one or more of SnS, SnSe, SnTe, PbS, PbSe, PbTe, SnSeS, SnSeTe, SnSTe, PbSeS, PbSeTe, PbSTe, SnPbS. SnPbSe, SnPbTe, SnPbSSe, SnPbSeTe, and SnPbSTe; the group III-V compound is selected from one or more of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP. GaInNAs, GaInNSb, GaInPAs, GaInPSb, InAlNP, InAlNAs, InAlNSb, InAlPAs, and InAlPSb; the group I-III-VI compound is selected from one or more of CuInS₂, CuInSe₂, and AgInS₂; the quantum dot with the core-shell structure is selected from one or more of CdSe/CdSeS/CdS, InP/ZnSeS/ZnS, CdZnSe/ZnSe/ZnS, CdSeS/ZnSeS/ZnS, CdSe/ZnS, CdSe/ZnSe/ZnS, ZnSe/ZnS, ZnSeTe/ZnS, CdSe/CdZnSeS/ZnS, and InP/ZnSe/ZnS; the perovskite-type quantum dot has a general structural formula of AMX₃, where A is selected from Cs⁺, CH₃(CH₂)ₙ₋₂NH₃⁺, or [NH₃(CH₂)ₙNH₃]²⁺, n is greater or equal to 2, M is selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, and Eu²⁺, and X is selected from one or more of Cl⁻, Br⁻, and I⁻.

7. The photoelectric device according to claim 5, wherein an average particle size of the second inorganic nanoparticle ranges from 7 nm to 15 nm; and
the organic emission material comprises one or more of 4,4′-bis(N-carbazole)-1,1′-biphenyl: tris[2-(p-tolyl)pyridinyl iridium (III)], 4,4′,4″-tris(carbazol-9-yl)triphenylamine: tris[2-(p-tolyl)pyridinyl iridium], diarylanthracene derivatives, stilbene aromatic derivatives, pyrene derivatives, fluorene derivatives, a TBPe fluorescent material, a TTPX fluorescent material, a TBRb fluorescent material, a DBP fluorescent material, a delayed fluorescence material, a TTA material, a TADF material, a polymer comprising a B-N covalent, a HLCT material, and an Exciplex luminescent material.

8. The photoelectric device according to claim 1, wherein the photoelectric device further comprises one or more of a first carrier functional layer and a second carrier functional layer, where the first carrier functional layer disposed between the first electrode and the modification layer, and a second carrier functional layer disposed between the optical functional layer and the second electrode.

9. The photoelectric device according to claim 8, wherein the first carrier functional layer is a hole functional layer, and the second carrier functional is an electron functional layer.

10. The photoelectric device according to claim 9, wherein a material of the hole functional layer comprises a second organic semiconductor material, an absolute value of a HOMO energy level of the hole functional layer is less than an absolute value of a HOMO energy level of the modification layer.

11. The photoelectric device according to claim 10, wherein the HOMO energy level of the hole functional layer ranges from −5.5 eV to −4.8 eV.

12. The photoelectric device according to claim 11, wherein the second organic semiconductor material comprises one or more of 4,4′-Bis(N-carbazolyl)-1,1′-biphenyl, N,N′-diphenyl-N,N′-bis(1-naphthyl)-1,1′-biphenyl-4,4′-diamine, N,N′-bis(3-methylphenyl)-N,N′-diphenyl-benzidine, N,N′-bis(3-methylphenyl)-N,N′-bis(phenyl)-spiro, N,N′-bis(4-(N,N′-diphenyl-amino)phenyl)-N,N′-diphenylbenzidine, 4,4′,4′-tris(N-carbazolyl)-triphenylamine, 4′,4″-tris(carbazol-9-yl)-triphenylamine, trichloroisocyanuric acid, a terbium-doped phosphate-based green luminescent material, hexaazatriphenylenehexacabonitrile, 4,4′,4″-tris(N-3-methylphenyl-N-phenylamino)triphen, poly(9,9-dioctylfluorene-co-N-(4-poly[(9,9′-dioctylfluorene-2,7-diyl)-co-(4,4′-(N-(4-sec-butylphenyl)diphenylamine), butylphenyl)diphenylamine)], poly[N,N′-bis(4-butylphenyl)-N,N′-bis(phenyl)-benzi, polyaniline, polypyrrole, poly(phenylenevinylene), poly[2-methoxy-5-(3′,7′-dimethyloctyloxy)-1,4-phenylenevinylene], copper (II) phthalocyanine, aromatic tertiary amine, polynuclear aromatic tertiary amine, N,N,N′,N′-tetraphenylbenzidine, PEDOT, PEDOT:PSS and derivatives thereof, PEDOT:PSS doped with s-MoO₃, poly(N-vinylcarbazole) and derivatives thereof, polymethacrylate and derivatives thereof, poly(9,9-octylfluorene) and derivatives thereof, poly(spirofluorene) and derivatives thereof, N,N′-bis(naphthalen-1-yl)-N,N′-diphenylbenzidine, spiro-NPB, nano-polycrystalline diamond, microcrystalline cellulose, and tetracyanoquinone dimethane:
a material of the electron functional layer comprises one or more of a first doped-type metal oxide particle, a first undoped-type metal oxide particle, and a group IIB-VIA semiconductor material; the first undoped-type metal oxide particle comprises one or more of ZnO, TiO₂, and SnO₂; the first doped-type metal oxide particle comprises one or more of ZnO, TiO₂, and SnO₂, and a doping element of the first doped-type metal oxide particle comprises one or more of Al, Mg, Li, Mn, Y, La, Cu, Ni, Zr, Ce, In, and Ga; and
the anode and the cathode each independently comprise one or more of a metal, a carbon material, and a metal oxide: the metal comprises one or more of Al, Ag, Cu, Mo, Au, Ba, Ca, Yb and Mg: the carbon material comprises one or more of graphite, carbon nanotube, graphene, and carbon fiber: the metal oxide comprises one or more of indium tin oxide fluorine-doped tin oxide, antimony tin oxide, aluminium-doped zinc oxide, gallium-doped zinc oxide, indium-doped zinc oxide, magnesium-doped zinc oxide, and MoO₃.

13. A method for preparing a photoelectric device comprising:
providing a preform comprising a first electrode:
disposing a first organic semiconductor material and a first inorganic nanoparticle on the preform to form a modification layer: and
forming an optical functional layer and a second electrode sequentially on the modification layer.

14. The method according to claim 13, wherein a method for preparing the modification layer comprises:
providing a mixed liquid comprising the first organic semiconductor material, the first inorganic nanoparticle, and a solvent: and
disposing the mixed liquid on the preform to form a modification layer.

15. The method according to claim 14, wherein in the mixed liquid, a mass ratio of the first organic semiconductor material to the first inorganic nanoparticle is (90˜99):(1˜10);
in the mixed liquid, a mass concentration of the first organic semiconductor material ranges from 8 mg/mL to 15 mg/mL, and the solvent comprises one or more of chlorobenzene, diethylene glycol monobutyl ether, 3-methoxy-1-butanol, triethylene glycol monobutyl ether, diglyme, methanol, ethanol, 1-propanol, butanol, ethylene glycol, isopropanol, glycerol, dimethyl sulfoxide, acetone, acetophenone, tetrahydrofuran, N,N-dimethylformamide,, ethyl acetate, pyrrole, butyric acid, and cresol; and
After disposing the mixed liquid on the preform, the method further comprises a thermal annealing.

16. The method according to claim 13, wherein the preform further comprises a first carrier functional layer stacked with the first electrode: and
forming an optical functional layer on the modification layer comprises forming a second carrier functional layer on the modification layer, and forming a second electrode on the second carrier functional layer.

17. A method for preparing a photoelectric device comprising:
providing a preform comprising a second electrode and an optical functional layer disposed in stack:
disposing a first organic semiconductor material and a first inorganic nanoparticle on the preform to form a modification layer; and
forming a first electrode on the modification layer.

18. The method according to claim 17, wherein a method for preparing the modification layer comprises:
providing a mixed liquid comprising the first organic semiconductor material, the first inorganic nanoparticle, and a solvent; and
disposing the mixed liquid on the preform to form a modification layer.

19. The method according to claim 18, wherein in the mixed liquid, a mass ratio of the first organic semiconductor material to the first inorganic nanoparticle is (90˜99):(1˜10);
a mass concentration of the first organic semiconductor material ranges from 8 mg/mL to 15 mg/mL, and the solvent comprises one or more of chlorobenzene, diethylene glycol monobutyl ether, 3-methoxy-1-butanol, triethylene glycol monobutyl ether, diglyme, methanol, ethanol, 1-propanol, butanol, ethylene glycol, isopropanol, glycerol, dimethyl sulfoxide, acetone, acetophenone, tetrahydrofuran, N,N-dimethylformamide,, ethyl acetate, pyrrole, butyric acid, and cresol;
After disposing the mixed liquid on the preform, the method further comprises a thermal annealing.

20. The method according to claim 17, wherein the preform further comprises a second carrier functional layer disposed between the second electrode and the optical function layer; and
forming a first electrode on the modification layer comprises forming a first carrier functional layer on the modification layer, and forming a first electrode on the first carrier functional layer.
